(19) United States
(12) Patent Application Publication
(10) Pub. No.: US 2022/0050427 A1
(43) Pub. Date: Feb. 17, 2022

(54) SYSTEMS AND METHODS FOR SUPERVISION OF LOCAL ANALYTICS

(71) Applicant: 3M INNOVATIVE PROPERTIES COMPANY, St. Paul, MN (US)

(72) Inventors: Brian E. Brooks, St. Paul, MN (US); Gilles J. Benoit, Minneapolis, MN (US)

(73) Assignee: 3M Innovative Properties Company

(21) Appl. No.: 17/511,934

(22) Filed: Oct. 27, 2021

Related U.S. Application Data
(62) Division of application No. 16/335,280, filed on Mar. 21, 2019.
(60) Provisional application No. 62/420,137, filed on Nov. 10, 2016.

(51) Int. Cl. G05B 13/04; G06F 30/00; G06F 17/18; G06K 9/62; G06N 7/00

(52) U.S. Cl. CPC G05B 13/04; G06F 30/00; G06N 7/005; G06K 9/6217; G06F 17/18

(57) ABSTRACT

Systems and methods for dynamically optimizing models used for sensor data analytics. An action is taken based on an analytics determination by systematically varying parameters of the analytical model using actions taken based on the analytics to determine the relative frequencies of hits, misses, false alarms, and correct rejections for particular model parameters. The model parameters for local analytics are selected based upon on signal detection theory analysis and the value or cost of each hit, miss, false alarm, or correct rejection.

### CROSS REFERENCE TO RELATED APPLICATIONS

This application is a divisional of U.S. application Ser. No. 16/335,280, filed Mar. 21, 2019, which is a national stage filing under 35 U.S.C. 371 of PCT/IB2017/056873, filed Nov. 3, 2017, which claims the benefit of U.S. Provisional Application No. 62/420,137, filed Nov. 10, 2016, the disclosures of which are incorporated by reference in their entireties herein.

### BACKGROUND

As the “Internet of Things” grows, more and more devices have sensors and processing power embedded in them. While this can offer intelligent operations (advanced criteria for alarms, indicators of part wear in devices, etc.), these embedded analytics are often slow to update, in part due to pre-programming of the models and basing the analytical methods and parameters off of pre-computed models. The models are often based on either first principles or “big data” driven aggregation of historical data; either of these approaches will contain imprecision due to assumptions, and in the case of aggregate data, the existence of third variables and directionality questions. These modeling approaches are also limited in their ability to recognize errors and self-correct, due to the lack of experimental control and the use of aggregate, passively collected data. Also, errors in these models can become increasingly costly or risky as they are applied to expensive capital equipment, for example for diagnosing maintenance needs in jet engines, or oil excavation equipment, faults on electrical grids, or when applied to safety issues, such as the use of remote sensors to guide decision-making around entering potentially hazardous sites such as methane leak sites.

Further, these models may not be frequently updated, often only being updated in new product generations, and tend to be general for the device; while some large installations may include tailoring to particular operational conditions or environments, there is insufficient scalability for updating and adapting the analytical modules, on many other devices with local analytics, including both selecting models and tuning their parameters. Automating the process may offer a more scalable way to tune local analytics for particular contexts or deployments.

Signal detection theory is a framework for analyzing the effectiveness of responding to particular signals, which has been used in air traffic controller evaluations, medicine, and forensic science. The framework breaks outcomes down into 4 categories, based on whether an action was taken, and whether the condition requiring the action was indeed present. Those categories are hits (where an action is taken and the condition is present), misses (where no action is taken, but the condition is present), false alarms (where action is taken but the condition is not present) and correct rejections (where action is not taken and the condition is not present). The four outcomes are all interrelated; for example, adjusting decision criteria to drive up the rate of hits necessarily also increases the incidence of false alarms for a given set of sensor characteristics (i.e. d-prime). From the distribution of those four outcomes, signal detection theory allows separate and independent values can be computed for both the sensitivity of the sensors and the accuracy of the response criteria, allowing for each element to be optimized. However, this optimization requires the separation of these two aspects of responding to signals to make it possible to isolate and optimize the response criteria; this is difficult if not impossible to achieve through analysis of historical data without an ability to control the confounds that affect these metrics, including their influence on one another when one cannot be known or controlled for.

Natural gas utilities often must monitor a critical point, for example when an emergency responder visits the site, evacuates it, and inspects it, using a hand-held methane detector while proceeding through the site until the levels reach an unsafe level, or when utility personnel must monitor capped well-heads, or monitoring low-level leaks to ensure they do not worsen. Electrical utilities must locate and characterize faults on their grids, and respond to those faults. In the emergency response example for gas utilities, he gas is typically then shut off remotely, and it is up to the unaided human judgment of the emergency responder to determine when to check a site. Should the emergency responder return to a site too early, this would expose them to the risk of explosion, and would count as a “false alarm” under signal detection theory, taking action when the event spurring the action (i.e. that gas levels had dropped below dangerous levels) has not actually occurred. However, the longer the responder waits, the longer the site is out of service, including leaving industrial sites idle or residents barred from entering their homes; this counts as a “miss” under signal detection theory, failing to recognize when an action should be taken. Remote sensors may offer some additional situational intelligence to support the emergency responder, but the behavior of gas within structures and its relationship to the overall safety to return to the leak site is not straightforward, requiring analytical tools evaluating the outputs of multiple sensors to provide an actionable recommendation that will increase the fraction of hits and correct rejections, maintaining responder safety while providing timely clearing of leak sites.

### SUMMARY

Methods for continuously updating and improving decision support provided by local analytics by: selecting specific models and/or model parameters for local analytics devices according to the likelihood that model will yield the proper ratio of hits, misses, false alarms and correct rejections based on the cost or benefit of each of those outcomes, responding to action triggers resulting from the models being applied by the local analytics devices, categorizing the outcomes of the response, in some cases through reference to other, yoked model selections for other local analytics devices in order to determine misses and correct rejections, and updating a database of models and outcomes used for selecting model parameters.

Systems for updating and improving local analytics criteria, which comprise a processor configured to determine a model for analytics, a response asset that may be activated by communications from a local analytics unit, and a database of models for analytics and their resulting outcomes, as well as a local analytics unit which comprises at least a model memory, one or more sensors, and a processor configured to determine the occurrence of an action trigger using the model in the model memory and the outputs of the one or more sensors.

### BRIEF DESCRIPTION OF THE DRAWINGS

FIG. 1 is a process flow diagram for an example method of the invention applied to updating local analytics.

FIG. 2 is a process flow diagram for an example method of the invention specifically directed to adjusting thresholds in remote gas monitoring systems.

FIG. 3 is a system diagram for an example system of local analytics modules.

FIG. 4 is a system diagram for an example system of remote gas sensors.

### DETAILED DESCRIPTION

Analytics evaluating sensor data, either at a local processor on a device, or acting on sensor data uploaded to the cloud, frequently triggers another event, which may confirm or refute the accuracy of the analytics determination by introducing additional resources beyond the sensor data being interpreted by the analytics. This allows local analytics determinations to be self-correcting and adaptive over time, both within and across devices by offering a feedback loop through which the local analytics determination may have its accuracy evaluated. For example, a device may trigger maintenance warnings at certain performance thresholds and/or runtime thresholds, or remote sensors may trigger a response to a condition, such as indicating that a natural gas leak site is now safe to visit and re-check; in all of these cases, the analytical model used may sometimes have false alarms or misses which may be costly or even dangerous.

Local analytics devices are devices with embedded sensors, processors, and communications which may be used to determine and respond to conditions at the device, including both internal device condition and events at or in proximity to the device. This may include measurements of run-time or parts wear indicating a need for maintenance, remote sensor applications providing information on state changes within (e.g. a set of remote methane sensors to provide ongoing monitoring of a leak site). The responses or actions triggered by the local analytics devices may be from external actors or devices in communication with the local analytics device (i.e. performing maintenance or having an asset visit and inspect a monitored leak site) or may be performed by the device itself, for example a capacitor bank automatically switching on based on local determination of power factor based on voltage and current measurements at or near the device.

Local analytics devices interpret the sensor outputs using a processor by using a model to link the sensor outputs with particular events and action triggers (i.e. when a value indicates that maintenance or replacement is required, or when it is likely that a gas leak has been stopped, or if the leak has become more severe) in order to identify and respond to the occurrence of particular conditions or events requiring response. The models may include, for example, threshold values for certain sensor readings such as a runtime after which a maintenance is to be performed, may be based on relationships among sensor readings, such as differences among readings from multiple gas sensors and comparisons being used to determine changes in state of the leak site, based on ranges such as having particular ranges of power quality within which a capacitor will be switched from off to on or vice versa, or other functions for event detection or action triggering based on the sensor outputs and model parameters. Model parameters include the function used to interpret the sensor results and values such as particular thresholds and ranges used in those interpretations.

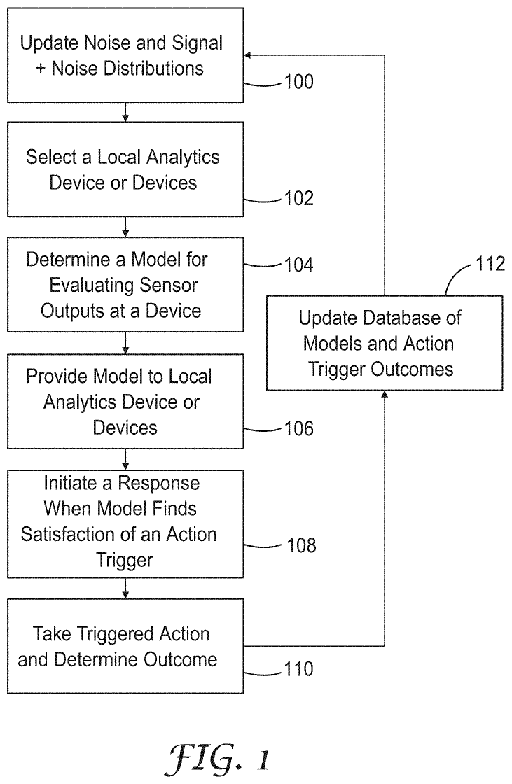

A method for dynamically adjusting the analytics criteria for a local device is depicted in FIG. 1. The method begins with updating noise and signal plus noise distributions for local analytics in step 100, and the selecting a local analytics device or set of devices in step 102. A model for evaluating sensor outputs at the selected device or set of devices is determined in step 104, based on a database of models and resulting outcomes of actions triggered using those models. The determined model is provided to the local analytics device in step 106, and is used to evaluate incoming sensor data at the device, including initiating a response when an action trigger included in the model is satisfied, in step 108. The satisfaction of the action trigger in step 108 drives the action taken in step 110, which also includes a determination of whether the action trigger provided a hit, a miss, a false alarm or a correct rejection. This outcome captured in step 110 is then added to a database of models and action trigger outcomes in step 112, which may be used in subsequent determinations of models for local analytics in later iterations of step 104.

Noise distributions and signal plus noise distributions are updated in step 100, based on outcome data, and may be used to compute a current value for beta-optimal. Beta-optimal indicates the desired decision criteria according to signal detection theory, resulting in an optimal distribution of hits (where a condition is successfully detected and responded to), misses (where a condition exists but is not detected), false alarms (where a response is triggered, but the condition does not actually exist) and correct rejections (where the condition does not exist, and no response is triggered) given the relationships among those outcomes. It may be computed from a value assigned to each outcome, and a sensitivity value for the sensors which is referred to in signal detection theory as d-prime. D-prime may account for not only the precision of the sensors themselves, but the sensitivity of a particular configuration of the sensors or a deployment protocol which is followed in placing the sensors. The d-prime value may be known for a given set of sensors used in a local analytics device, and that known value input via a user interface or retrieved from a memory for use in the computation of the beta-optimal value. The beta-optimal value may be specific to an individual local analytics device or general to a class of local analytics devices having similar sensing characteristics, operational contexts and/or value or consequences of each outcome. Beta-optimal may be computed based on the relative value of each outcome and data on the previous distribution of outcomes according to signal detection theory, for example by: determining the noise distribution p(N) by computing the number of false alarms and correct rejections divided by the total number of outcomes, determining the signal-plus-noise distribution p(SN) by computing 1-p(N), and computing beta optimal by dividing p(N) by p(SN) and multiplying that value by (V(CR)-C(FA))/(V(H)-C(M)) where V(CR) is the value of a correct rejection, C(FA) is the cost of a false alarm, V(H) is the value of a hit, and C(M) is the cost of a miss. Beta-optimal may be re-calculated across iterations of this method as additional data on outcomes is generated, and may be updated as data regarding the values and costs for outcomes change over time.

Selecting a local analytics device or devices in step 102 is performed by identifying one or more of the local analytics devices for which the model used in performing local analytics is to be determined. This selection may be based on deployment of the local analytics device (i.e. placing remote methane sensors at a gas leak site), the completion of a prior iteration of the method at a local analytics device or devices (i.e. when a device is receiving maintenance following a request based on local analytics under a previous model), or based on a schedule.

Determining a model for evaluating sensor outputs at a device is performed in step 104. The model is determined by selecting a model from a set of models. The models are methods for determining the condition of a site or device based on sensor inputs such as algorithms, formulae, mathematical or statistical models which may be executed by a processor at a local analytics device selected in step 102. The set of models from which the model to be used is selected are all directed towards making the same determination of site or device conditions, for example identifying when a device needs maintenance or when a site where there has been a methane leak has experienced a change in state relative to gas concentrations. The models may differ in methodology (for example, using pure runtime to determine maintenance need or requiring a certain threshold level of change in key performance metrics to determine that maintenance need) and/or in parameters (for example, each model using different weighting or scaling factors, delay periods, or threshold values). Each model is associated with a set of outcomes (hits, misses, correct rejections and false alarms) from previous iterations of this method. That set of outcomes is used to compute a d-prime value which characterizes the sensitivity of the model and establishes confidence intervals around the beta value based on the sample size (i.e. total number of logged outcomes). Model selection may be performed based on the d-prime values, confidence intervals, and their overlap with one another, to select among models most likely to have the highest sensitivity. This selection may, for example, be done through computing a likelihood that each model would have the highest value for d-prime. From that computed likelihood of highest d-prime the model is selected based on constrained randomization wherein the probability of selecting a model is determined by its likelihood of having the highest d-prime. For example, if Model 1 is 70% likely to have the highest d-prime based on the overlap of confidence intervals, Model 2 is 20% likely to have the highest d-prime, Model 3 is 0% likely to have the highest d-prime, and Model 4 is 10% likely to have the highest d-prime, the randomization will be weighted to match that, such that there is a 70% chance of selecting Model 1, a 20% chance of selecting Model 2, a 0% chance of selecting Model 3, and a 10% chance of selecting Model 4 as the determined threshold value for the sensor deployment.

In some embodiments, the model assigned to the local analytics device in step 106 may also be paired with one or more yoked controls to further enhance the ability to link models with particular outcomes (in situations where a response has not yet been made), providing the correct rejection and miss determinations which required to compute ROC curves and perform signal detection analyses. Yoked controls may be associated with one another by determining stochastic equivalence among the deployments of local analytics models and associating two or more stochastically equivalent deployments of local analytics models with one another. Stochastic equivalence among yoked controls enables the determination of group means for outcomes in an unbiased fashion, by ensuring significant, if not complete, overlap among the probabilities of the possible outcomes. This overlap in probabilities is based on the similarity of the situations and likely probability distributions of outcomes for those assignments of local analytics models to local analytics devices which may then be yoked together. Stochastic equivalence may be determined, for example, by considering all of a particular model or class of local analytics devices to be equivalent, considering particular deployment protocols for the local analytics device (i.e. placement of methane sensors at a gas leak site according to particular rules or heuristics), or, for example, based on similarity scores computed for the particular deployments of local analytics devices based on characteristics surrounding them (for example, for measuring wear on oil pumps, the viscosity and presence of particulate matter in the pumped oil may be used to compute which pumps may be sufficiently equivalent for pairing as yoked controls). Once determined, these associations may be stored in a database, for example as a field accompanying each assignment of a local analytics model to a local analytics device.

Providing a model to a local analytics device or devices is performed in step 106. The model determined in step 104 is provided to the local analytics device, by wired or wireless communications such as Ethernet protocols, WIFI communications (e.g. 802.11 standards), the BLUETOOTH technology, the ZIGBEE products, or other such communications enabling the data of the model to be communicated to the local analytics device or devices. When received by the local analytics device or devices, the model may be stored in a memory, to be used by a processor to determine when action triggers in the model have been satisfied by sensor readings at the local analytics device or devices.

Initiating a response when the model finds satisfaction of an action trigger occurs in step 108. A processor at the local analytics device receives the outputs of sensors at or near the local analytics device and using the model determined in step 104 and provided to the device in step 106, and when the sensor outputs satisfy triggers set in the model, the response is initiated by taking the action defined by the trigger in the model. This initiation of response may be communicating a request or change of state (i.e. indicating a change in conditions at a leak site and requesting personnel to examine the site) or in some embodiments, may be initiating an automated action such as sending a signal within the local analytics device to drive the switching of a capacitor bank from an off state to an on state or vice versa.

Taking the triggered action and recording an outcome occurs in step 110. In embodiments where the initiation of step 108 is a communication, step 110 is performed by taking the action requested by the communication, for example dispatching a maintenance crew to the local analytics device and performing maintenance, or visiting a gas leak site to investigate following a communication indicating a change of state. In these embodiments, the outcome of the local analytics device determination is measured during the response to the communication, for example the personnel performing maintenance record whether the maintenance was required or not. These determinations are recorded, and are used in step 112 to determine whether the model in this iteration of the process produced a hit, a miss, a correct rejection and/or a false alarm in triggering the response based on sensor outputs. In embodiments where the initiation of step 108 is the initiation of an automated action, step 110 is performed by completing that particular action, such as completing the physical switching of the state of a capacitor bank. In these embodiments, sensors outside the local analytics device may be used to determine the occurrence of a hit, miss, false alarm or correct rejection, for example for a capacitor bank switch, determining whether power factor has moved closer to or further from unity following the switching of that capacitor bank.

In some embodiments, determinations of misses and correct rejections may be determined during or after the outcome determination of step 110 by referencing the outcome of one or more yoked trials associated with the model during step 106. This determination is made by identifying whether the associated yoked trials are a higher or lower standard for the action trigger. Whether the standard is higher or lower may be determined by comparing the rate of triggering action responses for the yoked trial model to the rate of triggering action responses for the model, with a higher rate of action responses indicating a lower standard and a lower rate of action responses indicating a higher standard.

When the outcome determined by the action response is a “hit,” if a yoked trial that has a lower standard also yields a hit, the outcome determination may be changed to a “miss”, in that the condition may have been able to be detected and responded to earlier, according to the yoked trial with a lower standard providing a hit. When a lower standard yoked trial yields a false alarm, a “hit” remains a “hit.” Where the outcome determined by the action response is a “hit,” and a yoked trial with a lower standard yields a “false alarm,” the outcome determination may additionally be labeled a “correct rejection.” In some examples, outside data may also be used to supplement the determination of misses and correct rejections. For example, if an incident occurs (and this incident is detected and logged through another system interfacing with a system performing this example method, or entered via a user interface) without the local analytics unit having detected it and triggering a response, that data may be used to define the performance of the assigned local analytics model as a “miss.”

Updating the database of models and action trigger outcomes is performed in step 112. Once the outcome of a hit, miss, false alarm or correct rejection for the model is determined, the outcome is added to the database, adding that result to a set of results for the model which was selected in step 104 and further refining the understanding of the relative frequencies of hits, misses, false alarms and correct rejections when that model is applied at local analytics device. The updated database may then be referenced in subsequent iterations of this method, at step 104 for determining model parameters and/or selecting a model for a local analytics device.

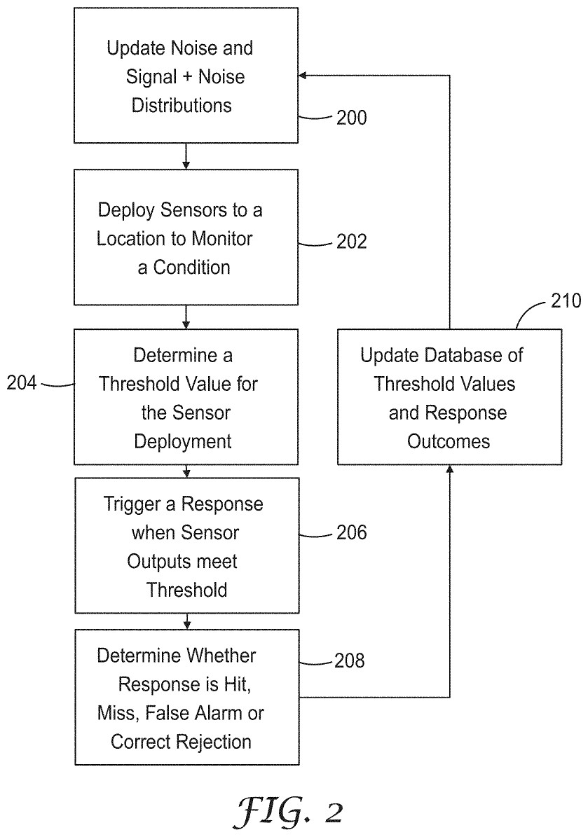

One particular example method relating to adjusting response criteria in remote gas sensors is depicted in FIG. 2. In this example, a plurality of sensors are left at a leak site for a gas such as methane, and the readings from the multiple sensors are evaluated to determine when the site may be re-checked, based on a high likelihood of site safety. In this example method, the beta-optimal for determining leak site condition is computed in step 200. Sensors are deployed to monitor a site condition in step 202, and a threshold value for the sensors is determined in step 204; these steps may be in the order presented, or may be concurrent or the order reversed, with threshold values determined prior to sensor deployment, depending on the condition and operational context. Once the threshold is determined and the sensors deployed to a site, the sensors monitor the site, and during this monitoring, the threshold is triggered in step 206. Once the threshold is met, the site is re-evaluated and that in that re-evaluation, it is determined whether the triggering of the threshold was a hit, miss, false alarm or correct rejection in step 208. The outcome determined in step 208 is then added to a database of thresholds and response outcomes in step 210, which may be used in subsequent determinations of threshold values according to step 204 in later iterations of this method.

Noise and signal plus noise distributions for the gas sensing models are computed in step 200. The beta-optimal may be computed from these distributions in addition to data on the relative costs and/or benefits of a particular outcome in the context of returning to a gas leak site, for example a large cost for a return to a site where there is still a dangerous level of gas, a small cost for missing an opportunity to return to and clear a site sooner, and benefits to correctly identifying that a site is not suitable to return to currently and to identifying promptly when a site can be re-entered and cleared. The cost and/or benefit data may be user-determined or derived from other data such as financial or risk models. Beta-optimal is computed as described above in step 100, using the value of each outcome, and may be computed for each iteration of this process.

Deploying sensors to a location is performed in step 202. One or more remote gas sensor units, for example methane sensors, are deployed to the leak location in accordance with a deployment protocol, to the extent possible according to the protocol and the permissible levels of gas compared to quantities that may trigger an evacuation. A deployment protocol may indicate the number of sensors to be deployed and locations to place the sensors, based on, for example, particular rooms to place sensors in, or the heights at which sensors should be placed. Once the sensors are deployed, in some embodiments the deployment and the extent to which it was performed may be confirmed, for example through utility maintenance personnel interacting with a user interface to confirm the number of sensors placed and whether they were placed as defined in the deployment protocol.

Determination of a threshold value or values for the sensors is performed in step 204. The threshold value corresponds to when sensor readings may be indicative of a change in state, for example dissipation of gas following shutoff of gas flow to the leak site. The threshold value may be in terms of relationships among sensor outputs, relationships of sensor values to initial and/or peak measured values, or absolute levels of a sensed gas such as methane. The threshold value may be determined from a set of potential values which may be user-determined or procedurally generated based on permissible ranges and boundaries set by users and/or data from previous iterations of methods of the invention. Each threshold value has an associated beta value computed from the distribution of hits, misses, correct rejections and false alarms which occurred in previous iterations of the method and which are stored in a database of thresholds and outcomes. These beta values have confidence intervals around them, which may be computed based on the current sample size (the total number of data points, i.e. the sum of the totals of hits, misses, correct rejections and false alarms). For one or more threshold values, the overlap of the confidence intervals around each d-prime value may be used to determine a likelihood that a particular threshold value will provide the best sensitivity. From that likelihood, the threshold value may be determined through weighted randomization based on the likelihood that the threshold value is the best option. For example, if Threshold Value 1 is 70% likely to have the highest d-prime, Threshold Value 2 is 20% likely to have the highest d-prime,, Threshold Value 3 is 0% likely to have the highest d-prime,, and Threshold Value 4 is 10% likely to have the highest d-prime,, the randomization will be weighted to match that, such that there is a 70% chance of selecting Threshold Value 1, a 20% chance of selecting Threshold Value 2, a 0% chance of selecting Threshold Value 3, and a 10% chance of selecting Threshold Value 4 as the determined threshold value to be used with the sensor deployment.

In some embodiments, the determination of the threshold value in step 204 is based on the deployment of the sensors in step 202. In these embodiments, the particular deployment and in some embodiments the extent the deployment was completed may be used to reference a database and retrieve a d-prime value and/or access historical outcome data for the particular deployment, for use in determining the threshold value in step 204. In some embodiments, the threshold value may be determined prior to or concurrent with the deployment of the sensors in step 202, using set values determined by the sensors, the type of deployment location, or an assumption that a particular protocol is used and fully implemented.

A response is triggered when the threshold value is satisfied in step 206. The remote gas sensors measure and regularly or continuously report their results, which are compared to the threshold determined in step 204 at a unit located at or near the remote gas sensors and in communication with those gas sensors, for example by wireless communications such as the ZIGBEE products, WIFI communications (802.11 protocols). When the most recently received sensor outputs are determined by a processor to satisfy the threshold, indicating a change in state at the leak site (i.e. levels dropping indicating successful gas shutoff and a need to re-check and clear the leak site), a message is sent via a communications link, for example wireless communications such as the ZIGBEE products, WIFI communications, the BLUETOOTH technology or cellular communications (i.e. 3G, 4G LTE) to a response asset; the response asset may be, for example, a mobile device carried by emergency response personnel such as the personnel who initially responded to the leak site and deployed the sensors in step 202.

Whether the response is a hit, miss, false alarm or a correct rejection is determined in step 208. When the response asset visits the leak site in accordance with the action trigger of step 206, the response asset independently measures gas levels at the site, for example using a hand-held methane sensor, and indicates whether the site was indeed safe to return; this may be done, for example, through a user interface on a device, such as an extension of the user interface used to confirm deployment protocols in some embodiments of step 202. In addition to this data from an individual visit, data from yoked trial associated with the current response may be used to identify correct rejections and misses.

Updating a database of threshold values and response outcomes is performed in step 210 by taking the outcome or outcomes determined in step 208, associating the outcome with the selected threshold value, and adding the associated outcome and threshold value to a database, which may optionally also include the deployment protocol for which the threshold value was selected. This database is used in determining the threshold values in step 204.

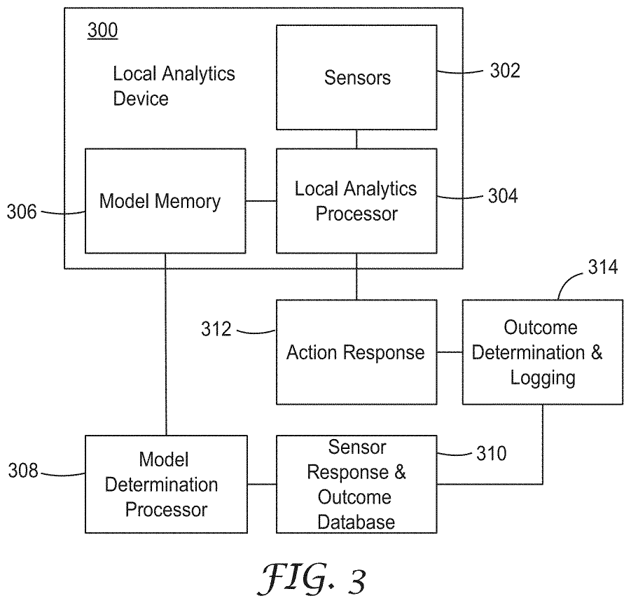

An example system with local analytics units that are dynamically updated to optimize model selection is depicted in FIG. 3. The system includes local analytics units 300, whose components include sensors 302, a local analytics processor 304 and a model memory 306. The local analytics device is connected communicatively to a model determination processor 308, and the local analytics processor 304 may trigger an action response unit 312. The action response 312 interacts with outcome determination and logging 314 to characterize the local analytics triggered response by the action response 312 as a hit, miss, correct rejection or false alarm, and the outcome determination and logging 314 provides this information to a memory configured to store a sensor response and outcome database 310. The processors and memories may be located together and coupled directly (e.g. wired together) or coupled only communicatively in a cloud architecture, transmitting the data among the elements via the Internet or other remote communications.

The local analytics unit 300 is a device which includes sensors 302, a local analytics processor 304 and model memory 306, using the sensors, processors and memories to evaluate conditions at the local analytics unit 300. The local analytics unit may be part of another device (for example, the sensors, processors and memories may be connected to parts of a pump, turbine, or engine) or may be the entire local analytics unit (for example, for a monitoring system for a gas leak site). The components of the local analytics unit are communicatively coupled to one another through wired or wireless means, but do not need to share a housing, and may be in proximity to one another (with the communicative coupling done wirelessly, for example through cellular, WIFI communications, the BLUETOOTH technology or the ZIGBEE products) or directly connected. The local analytics unit 300 may include wired or wireless communications to an action response 312 which may trigger a response under certain conditions such as when a device including the local analytics unit 300 needs maintenance, detects and in some examples characterizes a fault needing mitigation or resolution, or reports on a change in the state of a location such as a gas leak site becoming safe to enter.

The local analytics unit 300 includes sensors 302. The sensors may be, for example, counters for runtime, piezoelectric monitors of stress cycles, gas sensors such as methane sensors, current, voltage and/or other sensors for identifying and characterizing electrical faults, environmental sensors such as temperature sensors, pressure sensors for pipeline monitoring, or other sensors which provide information about a condition that may be responded to by an action response 312. The sensors produce outputs which may be raw electrical signals or which may be converted to digital values, and which are provided to the local analytics processor 304.

The local analytics unit 300 also includes a local analytics processor 304, configured to receive the sensor outputs and, using a model stored in model memory 306, determine a condition at or near the local analytics unit through interpretation of the sensor outputs. The local analytics processor may be a microprocessor of any standard, commercially available variety, and may be selected based on power consumption qualities or built into a microcontroller which may also include the model memory 306, inputs from the sensors 302 and an output to a communication antenna such as WIFI communications, the ZIGBEE products, the BLUETOOTH technology or cellular (i.e. 3G or 4G LTE).

The local analytics unit 300 also includes a model memory 306 configured to store a model for use in interpreting the outputs of sensors 302 by the local analytics processor 304. The model memory 306 may be a non-volatile memory such as flash memory or a hard disk drive. In some embodiments, the model memory 306 is coupled to a communications unit such as a cellular, WIFI communications, the BLUETOOTH technology or the ZIGBEE products antenna from which it received model data which is then stored in the model memory 306.

A model determination processor 308 is configured to set the parameters of a model which is provided to the local analytics processor 304 of the local analytics unit. The model determination processor is a processor configured to receive information from a database of local analytics models and their prior outcomes, and select a model to assign to a local analytics device 300. The determination may be made by computing the likelihood that a model is the best available model for use by the local analytics device from the hits, misses, false alarms and correct rejections for each potential model, for example by computing a beta value for the particular model and confidence intervals around it based on sample size and the distribution of outcomes and comparing those values to a determined optimal beta value. Using the computed likelihood for one or more models, a model may be selected, for example by using weighted randomization wherein the weighting for each model is determined based on those computed likelihoods.

A sensor response and outcome database 310 is a memory configured to store a database of the outcomes that result from using each model selected by the model determination processor 308 to evaluate output from sensors 302 at the local analytics processor 304. The information from this memory is used by the model determination processor 308 when determining the model to provide to the local analytics unit 300. The sensor response and outcome database may be stored on non-volatile memory such as one or more hard disk drives or flash memory.

Action response 312 is a unit or personnel which is separate from the local analytics device 300 but that respond to determinations by the local analytics processor 304 or has its actions queued in accordance with the outputs of the local analytics processor 304. Examples include an emergency response crews, such as gas distribution network emergency responders, or maintenance personnel on-call or queued to visit, inspect and maintain devices which automatically report wear states and maintenance needs.

An outcome determination and logging unit 314 characterizes the situation reported by the local analytics processor 304 based on the findings of the action response 312. This may be input through a user interface, based on output of sensors carried by the action response personnel or assets, or from other remote sensors near or at the local analytics unit, but separate from the sensors 302 and whose outputs are not considered by the local analytics processor 304. The outcomes determined and logged by this unit are added to the sensor response and outcome database 308. In some examples, the outcome determination performed by the unit may include reference to associated yoked trials, using the outcomes across two or more associated yoked trials to allow the determination of correct rejections and misses to provide the complete set of information required to determine the accuracy of local analytics models.

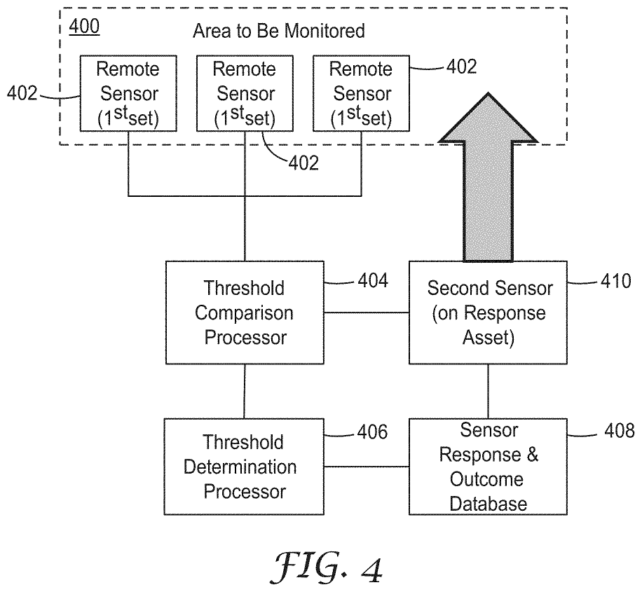

A particular example system where the local analytics unit is a set of remote gas sensors used to monitor a condition and trigger a re-entry and assessment of a leak site is depicted in FIG. 4. Sensors 402 are deployed in a monitoring site 400. The output of the sensors 402 is evaluated by a threshold comparison processor 404, which receives threshold values from a threshold determination processor 406, and the threshold comparison processor 404 directs a response asset including a second sensor 410 to enter the monitoring site 400. The second sensor 410 on the response asset communicates with a sensor response and outcome database 408 to provide feedback on site conditions and whether the conditions encountered by the response asset indicate a hit, miss, false alarm or correct rejection by the sensors 402 and the threshold comparison processor 404, and that result is stored with the associated threshold value in the sensor response and outcome database 408.

Leak site 400 is an area in which there may be a gas (typically methane, but may be other hazardous gases as well) leak, and the site will be monitored. The leak site may be identified by, for example, utility customers calling in when they smell the odor of natural gas. The leak site is a location where there may be a methane leak, such as a capped well head, a house from which a leak has been called in, and may include land surrounding structures as well as the structures themselves, or even include adjacent structures depending on the nature and severity of the possible leak and the timing of the response to that possible leak.

Sensors 402 are deployed to the leak site. The sensors may be gas sensors such as methane sensors or other hazardous gas sensors. The sensors 402 may be intrinsically safe, and may be any configuration or variety of methane sensor such as flame ionization, acoustic, or infrared. The sensors may be one or more remote sensors which are communicatively coupled through wired or wireless means (for example, the ZIGBEE products, WIFI communications, or cellular data such as 3G or 4G LTE connections) to one another and/or to a base station, all of which may be deployed to the leak site 400.

Threshold comparison processor 404 is configured to receive readings from sensors 402 and determine whether the sensor readings satisfy a threshold provided by the threshold determination processor 406 and stored in a memory coupled to the threshold comparison processor 404. The threshold may be, for example, a threshold value for any of the sensors 402, may be based on a threshold value for the reading of each of the sensors 402, or may be based on relationships among specific sensor 402 outputs given the deployment of those sensors according to a particular protocol (for example, comparing a sensor placed approximately 4 feet off the floor of the leak site 400 vs. another sensor placed 8 feet above the floor of the leak site 400). Threshold determination processor 406 is a processor configured to set a threshold value which is used to evaluate the output of sensors 402 to determine a change in state of the leak site 400. The determined threshold may be in terms of, for example, methane levels at individual sensors 402 or relationships among methane levels at different sensors 402 deployed to the leak site 400. The determination is made in part based on data from sensor and response outcome database 408, for example confidence intervals computed around the measured beta value (based on relative rates of hits, misses, false alarms and correct rejections in previous trials using that threshold) for each potential threshold to be selected from, and the overlap of those confidence intervals with a computed optimal value for beta.

Sensor response and outcome database 408 is a memory configured to store data relating to thresholds for detecting changes in state of leak site 400 based on the prior outputs of the threshold comparison processor 404 and the outcomes of those trials. Optionally, the database may include values assigned to each outcome (hit, miss, correct rejection, and false alarm) for the purpose of identifying the optimal beta value for threshold values used for making determinations of site condition. Optionally, the database may also include an association between a first threshold value and one or more other threshold values involved in a yoked trial, enabling outcomes for each threshold value to be used to determine the existence of misses and correct rejections for those particular yoked trials.

Second sensor 410 is a methane detector. The sensor may be integral with a response asset or a handheld sensor unit carried by response personnel. The sensor is separate from the remote sensor or networks of sensors 402. Second sensor 410 is used to measure the methane level at leak site 400 when it is visited by a response asset such as emergency first responders to a gas site. The reading taken by second sensor 410 may be added to the sensor response and outcome database 408 directly, or an outcome determined based on the output of second sensor 410 may be entered manually (by, for example, the emergency first responder's determination confirming that the site was suitable for re-entry or that the site was unsuitable for re-entry) through a user interface providing the outcome to the threshold and outcome database 408, or the results from the second sensor 410 may be provided to a processor which determines an outcome based on the sensor outputs and provides the outcome determination to the threshold and outcome database 408.

What is claimed is:

1. A method for evaluating a gas leak site, comprising:
selecting parameters for a model for converting methane sensor outputs to an assessment of site condition based on a database of model parameters and accuracy of determinations of changes in site condition;
deploying a plurality of remote methane sensing units to a site;
receiving sensor outputs from the plurality of remote methane sensing units;
determining a change in site condition based on the sensor outputs and the model revisiting the site based on the change in site condition; and
updating the database of model parameters and accuracy of determinations of changes in site condition based on the revisiting of the site.

2. The method of claim 1, wherein selecting parameters for a model comprises weighted randomization based on the overlap in confidence intervals for the accuracy of determinations of changes in site condition.

3. The method of claim 1, wherein selecting parameters for a model is performed according to yoked control experimental design.

4. The method of claim 1, wherein revisiting the site further comprises measuring the methane levels at the site.

5. The method of claim 1, wherein the accuracy of a determination of change in site condition is classified as a hit, miss, false alarm or correct rejection.

6. A system for evaluating a gas leak site, comprising:
a plurality of remote methane sensing units, each comprising a methane sensor and a wireless communications antenna;
a first processor configured to receive readings from the plurality of remote methane sensing units and determine site condition based on a model;
a second methane sensing unit that comprises a portable methane sensor;
a memory configured to store a database comprising the parameters of the model used by the first processor, the determinations of site condition, and accuracy data for the determinations of site condition; and
a second processor configured to determine model parameters based on the database stored in the memory.

7. The system of claim 6, wherein the second processor determined model parameters based on constrained randomization based on the overlap of confidence intervals around accuracy data for the determinations of site condition.

8. The system of claim 6, further comprising a processor configured to determine the accuracy of the site condition determination based on readings from the second methane sensing unit.

9. The system of claim 6, wherein the accuracy data for the determination of site condition is input through a user interface.
